(19) United States
(12) Patent Application Publication
(10) Pub. No.: US 2026/0156836 A1
(43) Pub. Date: Jun. 4, 2026

(54) SEMICONDUCTOR DEVICE HAVING THREE-DIMENSIONAL STRUCTURE

(71) Applicant: SAMSUNG ELECTRONICS CO., LTD., Suwon-si (KR)

(72) Inventors: Junghoon PARK, Suwon-si (KR); Juhyung KIM, Suwon-si (KR)

(73) Assignee: SAMSUNG ELECTRONICS CO., LTD., Suwon-si (KR)

(21) Appl. No.: 19/402,000

(22) Filed: Nov. 26, 2025

(30) Foreign Application Priority Data
Dec. 4, 2024 (KR) 10-2024-0178865

(51) Int. Cl. H10B 63/00

(52) U.S. Cl. CPC H10B 63/845; H10B 63/34

(57) ABSTRACT

A semiconductor device includes a plurality of gate electrodes arranged spaced apart from each other in a vertical direction on a substrate, a plurality of mold insulating layers alternately arranged with the plurality of gate electrodes on the substrate, a channel layer extending in the vertical direction by penetrating the plurality of gate electrodes and the plurality of mold insulating layers, and a plurality of electrochemical cells disposed in the vertical direction on a side wall of the channel layer, each of the plurality of electrochemical cells including a resistive switching layer, an electrolyte layer, and a reservoir layer, which are sequentially arranged on the side wall of the channel layer. The resistive switching layers, the electrolyte layers, and/or the reservoir layers of two electrochemical cells immediately adjacent to each other among the plurality of electrochemical cells are spaced apart from each other.

### CROSS-REFERENCE TO RELATED APPLICATION

This application is based on and claims priority under 35 U.S.C. § 119 to Korean Patent Application No. 10-2024-0178865, filed on Dec. 4, 2024, in the Korean Intellectual Property Office, the disclosure of which is incorporated by reference herein in its entirety.

### BACKGROUND

The inventive concept relates to a semiconductor device having a three-dimensional structure, and more particularly, to a semiconductor device having memory strings arranged in a vertical direction.

Memory devices capable of storing high capacity data are required in an electronic system needing data storage. As one of the methods to increase data storage capacity of semiconductor devices, a semiconductor device including three-dimensionally arranged memory cells instead of two-dimensionally arranged memory cells has been proposed.

### SUMMARY

The inventive concept provides a semiconductor device with excellent operation properties and improved integration.

According to an aspect of the inventive concept, there is provided a semiconductor device including a plurality of gate electrodes arranged spaced apart from each other in a vertical direction on a substrate, a plurality of mold insulating layers alternately arranged with the plurality of gate electrodes on the substrate, a channel layer extending in the vertical direction by penetrating the plurality of gate electrodes and the plurality of mold insulating layers, and a plurality of electrochemical cells disposed in the vertical direction on a side wall of the channel layer, each of the plurality of electrochemical cells including a resistive switching layer, an electrolyte layer, and a reservoir layer, which are sequentially arranged on the side wall of the channel layer. The resistive switching layers of two electrochemical cells immediately adjacent to each other among the plurality of electrochemical cells may be spaced apart from each other, the electrolyte layers of the two electrochemical cells immediately adjacent to each other among the plurality of electrochemical cells may be spaced apart from each other, and/or the reservoir layers of the two electrochemical cells immediately adjacent to each other among the plurality of electrochemical cells may be spaced apart from each other.

According to another aspect of the inventive concept, there is provided a semiconductor device including a plurality of gate electrodes and a plurality of mold insulating layers, which are alternately arranged on a substrate, a channel layer extending in a vertical direction by penetrating the plurality of gate electrodes and the plurality of mold insulating layers, and a plurality of electrochemical cells disposed in the vertical direction on a side wall of the channel layer, each of the plurality of electrochemical cells including a resistive switching layer, an electrolyte layer, and a reservoir layer, which are sequentially arranged on the side wall of the channel layer. Each of the plurality of mold insulating layers may include a ring portion disposed on the side wall of the channel layer, and the ring portion may be arranged between a first electrochemical cell and a second electrochemical cell among the plurality of electrochemical cells. The resistive switching layers of the first and second electrochemical cells may be spaced apart from each other, the electrolyte layers of the first and second electrochemical cells may be spaced apart from each other, and/or the reservoir layers of the first and second electrochemical cells may be spaced apart from each other.

According to another aspect of the inventive concept, there is provided a semiconductor device including a plurality of gate electrodes arranged spaced apart from each other in the vertical direction on a substrate, the plurality of gate electrodes including a first gate electrode and a second gate electrode, a channel layer extending in the vertical direction by penetrating the plurality of gate electrodes, a first electrochemical cell arranged between a first part of a side wall of the channel layer and the first gate electrode, and a second electrochemical cell arranged between a second part of the side wall of the channel layer and the second gate electrode, the second electrochemical cell overlapping the first electrochemical cell in the vertical direction. Each of the first electrochemical cell and the second electrochemical cell may include a resistive switching layer in contact with the channel layer, an electrolyte layer disposed on a side wall of the resistive switching layer, and a reservoir layer disposed on a side wall of the electrolyte layer. The resistive switching layers of the first and second electrochemical cells may be spaced apart from each other, the electrolyte layers of the first and second electrochemical cells may be spaced apart from each other, and/or the reservoir layers of the first and second electrochemical cells may be spaced apart from each other.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments;

FIG. 2 is a circuit diagram showing a memory cell block according to some embodiments;

FIG. 3 is a plan layout diagram showing a typical configuration of a semiconductor device according to some embodiments;

FIG. 4 is an enlarged layout diagram of a region A of FIG. 3;

FIG. 5 is a cross-sectional view of the semiconductor device taken along line B1-B1′ of FIG. 4;

FIG. 6 is a cross-sectional view of the semiconductor device taken along line B2-B2′ of FIG. 4;

FIG. 7 is an enlarged view of a region EN of FIG. 5.

FIG. 8 includes plan views of the semiconductor device at a first vertical level and a second vertical level in FIG. 7;

FIG. 9 is a schematic view showing a driving method in a programming mode and an erase mode of a semiconductor device according to some embodiments;

FIG. 10 is a schematic diagram showing oxygen vacancy migration in a programming mode within an electrochemical cell;

FIG. 11 is a schematic diagram showing oxygen vacancy migration in an erase mode within an electrochemical cell;

FIG. 12 is a cross-sectional view of a semiconductor device according to some embodiments;

FIG. 13 shows plan views of the semiconductor device at a first vertical level and a second vertical level in FIG. 12;

FIG. 14 is a cross-sectional view of a semiconductor device according to some embodiments;

FIG. 15 shows plan views of the semiconductor device at a first vertical level and a second vertical level in FIG. 14;

FIG. 16 is a cross-sectional view of a semiconductor device according to some embodiments;

FIG. 17 shows plan views of the semiconductor device at a first vertical level and a second vertical level in FIG. 16;

FIG. 18 is a cross-sectional view of a semiconductor device according to some embodiments;

FIG. 19 is a cross-sectional view of a semiconductor device according to some embodiments;

FIG. 20 is a schematic block diagram showing a data storage system including a semiconductor device according to some embodiments;

FIG. 21 is a schematic perspective view of a data storage system including a semiconductor device according to some embodiments; and

FIG. 22 is a schematic cross-sectional view of semiconductor packages according to some embodiments.

### DETAILED DESCRIPTION OF THE EMBODIMENTS

Hereinafter, embodiments of the inventive concept are described in detail with reference to the accompanying drawings.

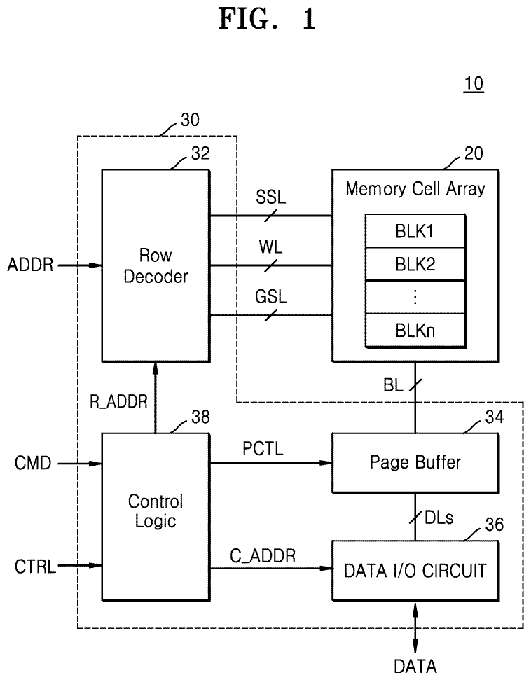

FIG. 1 is a block diagram of a semiconductor device 10 according to some embodiments.

Referring to FIG. 1, the semiconductor device 10 may include a memory cell array 20 and a peripheral circuit 30. The memory cell array 20 may include a plurality of memory cell blocks BLK1, BLK2, . . . , BLKn. The memory cell blocks BLK1, BLK2, . . . , BLKn may each include a plurality of memory cells. The memory cell blocks BLK1, BLK2, . . . , BLKn may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, and a control logic 38. Although not illustrated in FIG. 1, the peripheral circuit 30 may further include an I/O interface, a column logic, a voltage generator, a pre-decoder, a temperature sensor, a command decoder, an address decoder, an amplification circuit, or the like.

The memory cell array 20 may be connected to the page buffer 34 through the bit line BL, and to the row decoder 32 through the word line WL, the string select line SSL, and the ground select line GSL. In the memory cell array 20, a plurality of memory cells included in the memory cell blocks BLK1, BLK2, . . . , BLKn may each be a flash memory cell. The memory cell array 20 may include a three-dimensional memory cell array. The three-dimensional memory cell array may include a plurality of NAND strings, and each NAND string may include a plurality of memory cells connected to the word lines WL vertically stacked on a substrate.

The peripheral circuit 30 may receive an address ADDR, a command CMD, and a control signal CTRL from the outside of the semiconductor device 10, and transceive data DATA with a device outside the semiconductor device 10.

The row decoder 32 may select at least one of the memory cell blocks BLK1, BLK2, . . . , BLKn in response to the address ADDR from the outside, and may select the word line WL, the string select line SSL, and the ground select line GSL of the selected memory cell block. The row decoder 32 may transmit a voltage to perform a memory operation to the word line WL of the selected memory cell block.

The page buffer 34 may be connected to the memory cell array 20 through the bit line BL. The page buffer 34 may apply a voltage according to the data DATA to be stored in the memory cell array 20 to the bit line BL, by operating as a write driver in a program operation, and detect the data DATA stored in the memory cell array 20 by operating as a detection amplifier in a read-out operation. The page buffer 34 may operate according to a control signal PCTL provided from the control logic 38.

The data I/O circuit 36 may be connected to the page buffer 34 through data lines DLs. The data I/O circuit 36 in the program operation may receive the data DATA from a memory controller (not shown), and provide the program data DATA to the page buffer 34 based on a column address C_ADDR provided from the control logic 38. The data I/O circuit 36 in the read-out operation may provide the read-out data DATA stored in the page buffer 34 to the memory controller based on the column address C_ADDR provided from the control logic 38.

The data I/O circuit 36 may transmit an input address or instruction to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32, and provide the column address C_ADDR to the data I/O circuit 36. The control logic 38 may generate, in response to the control signal CTRL, various internal control signals used in the semiconductor device 10. For example, the control logic 38 may adjust the level of a voltage provided to the word line WL and the bit line BL during a memory operation, such as a program operation, an erase operation, or the like.

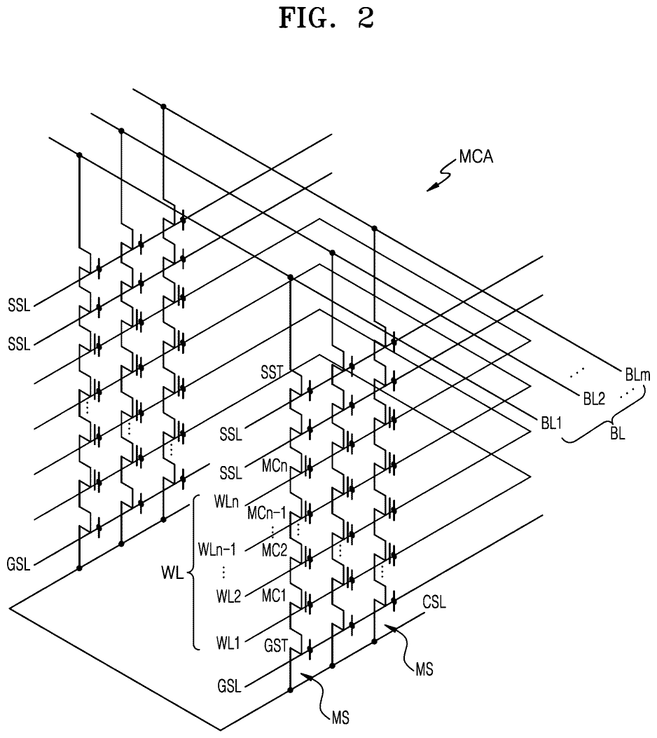

FIG. 2 is a circuit diagram a memory cell block BLK according to some embodiments.

Referring to FIG. 2, a memory cell array MCA may include a plurality of memory cell strings MS. The memory cell array MCA may include a plurality of bit lines BL: BL1, BL2, . . . , BLm, a plurality of word lines WL: WL1, WL2, . . . , WLn−1, and WLn, at least one string select line SSL, at least one ground select line GSL, and a common source line CSL. The memory cell strings MS may be formed between the bit lines BL: BL1, BL2, . . . , BLm and the common source line CSL. Although FIG. 2 illustrates a case in which each of the memory cell strings MS includes two string select lines SSL, the disclosure is not limited thereto. For example, the memory cell strings MS may each include one string select line SSL.

The memory cell strings MS may each include a string select transistor SST, a ground select transistor GST, and memory cell transistors MC1, MC2, . . . , MCn−1, and MCn. A drain region of the string select transistor SST may be connected to the bit lines BL: BL1, BL2, . . . , BLm, and a source region of the ground select transistor GST may be connected to the common source line CSL. The common source line CSL may be an area to which source regions of a plurality of ground select transistors GST are commonly connected.

The string select transistor SST may be connected to the string select line SSL, and the ground select transistor GST may be connected to the ground select line GSL. The memory cell transistors MC1, MC2, . . . , MCn−1, and MCn may be connected to the word lines WL: WL1, WL2, . . . , WLn−1, and WLn, respectively.

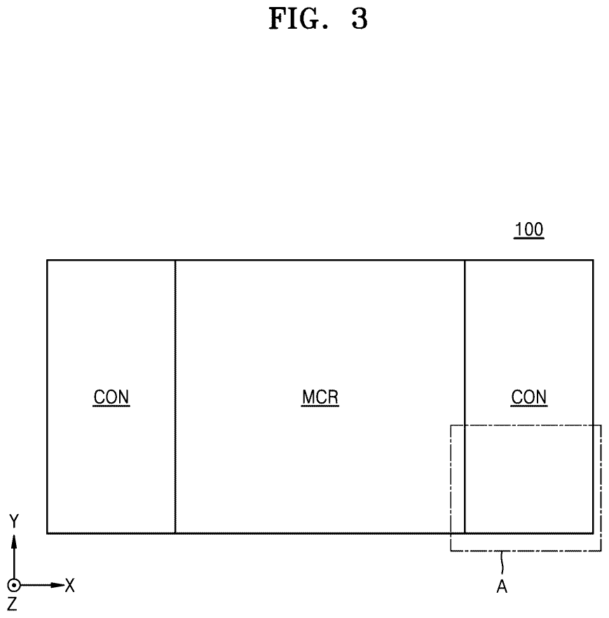

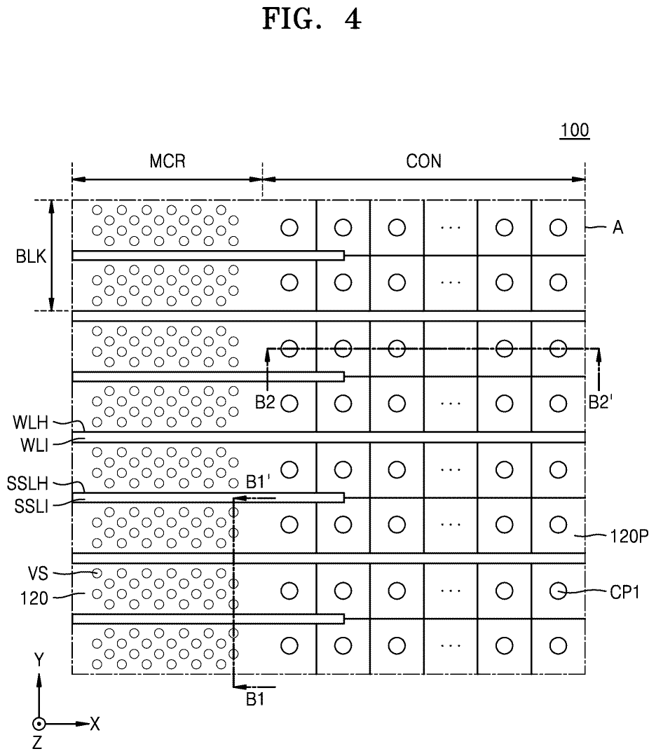

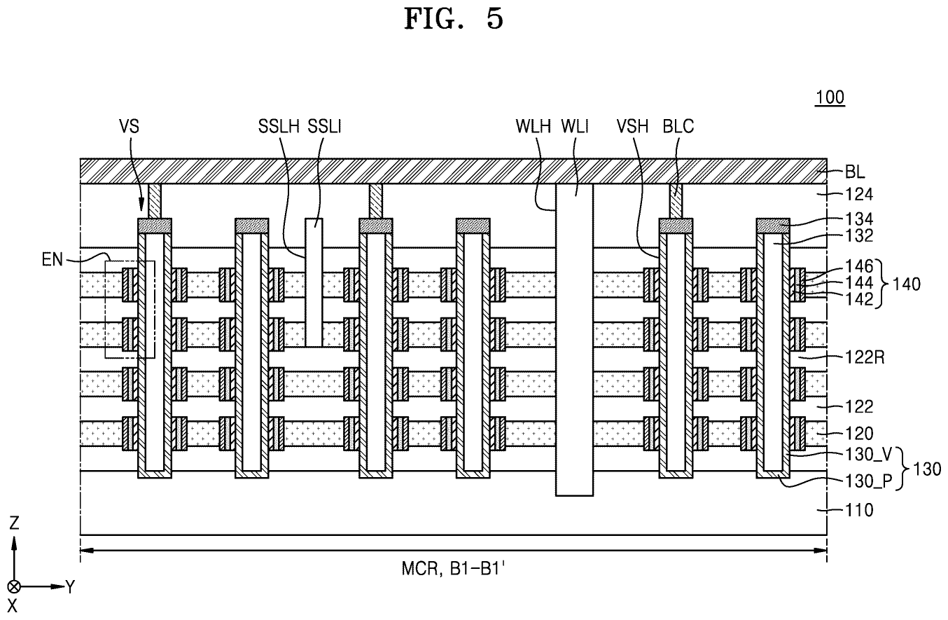

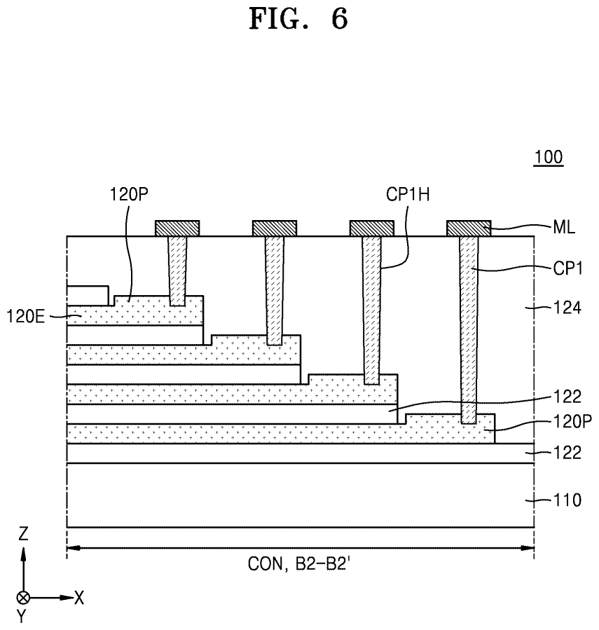

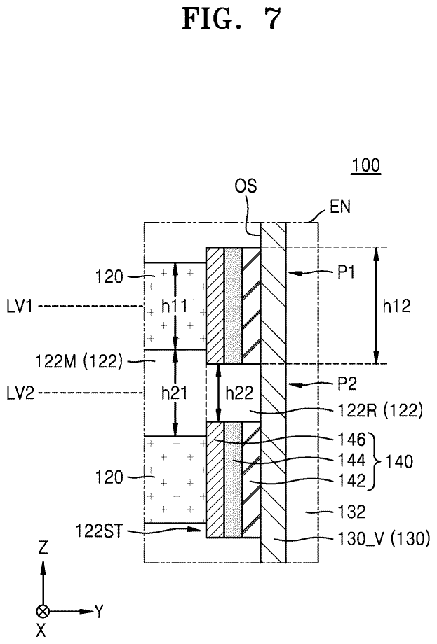

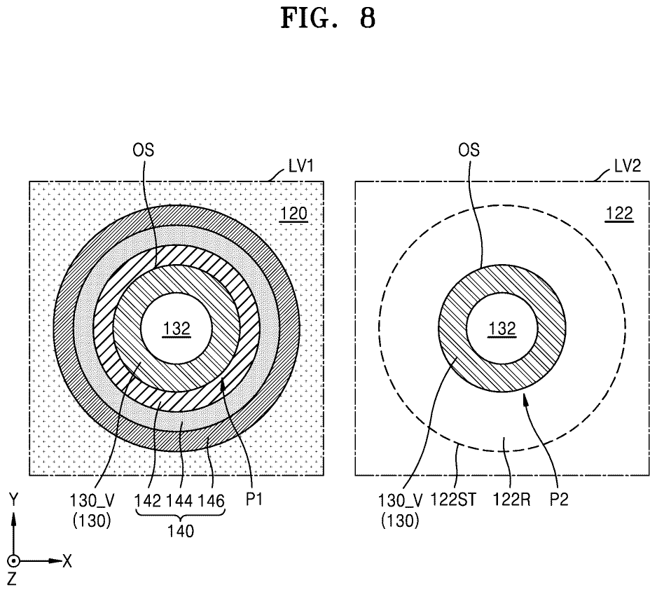

FIG. 3 is a plan layout diagram showing a typical configuration of a semiconductor device 100 according to some embodiments. FIG. 4 is an enlarged layout diagram of a region A of FIG. 3. FIG. 5 is a cross-sectional view of the semiconductor device taken along line B1-B1′ of FIG. 4. FIG. 6 is a cross-sectional view of the semiconductor device taken along line B2-B2′ of FIG. 4. FIG. 7 is an enlarged view of a region EN of FIG. 5. FIG. 8 includes plan views of the semiconductor device at a first vertical level LV1 and a second vertical level LV2 in FIG. 7.

Referring to FIGS. 3 to 8, the semiconductor device 100 may include a cell array region MCR and connection regions CON. The cell array region MCR may be arranged in the central area of a substrate 110, and the connection region CON may be disposed on the substrate 110 on both sides of the cell array region MCR.

The cell array region MCR may be where a plurality of memory cell blocks BLK are arranged. For example, the memory cell blocks BLK may each include a plurality of vertical structures VS extending in a vertical direction Z. The vertical structures VS may correspond to the memory cell strings MS described with reference to FIG. 2, respectively.

The connection region CON may provide an electrical connection for the memory cell blocks BLK, and may be where a gate pad portion 120P electrically connected to each of a plurality of gate electrodes 120 and a cell plug CP1 electrically connected to the gate pad portion 120P are arranged.

In some embodiments, a peripheral circuit area may be further arranged in a partial area of the substrate 110, and a peripheral circuit configured to drive the memory cell blocks BLK may be arranged in the peripheral circuit area. In other embodiments, a peripheral circuit may be disposed on a peripheral circuit board, and the substrate 110 may be disposed on the peripheral circuit board so that the peripheral circuit board and the substrate 110 may be at different vertical levels.

In the cell array region MCR, the gate electrodes 120 may be spaced apart from each other in the vertical direction Z on the substrate 110. The gate electrodes 120 may be alternately arranged with mold insulating layers 122, and each of the mold insulating layers 122 may be arranged between two adjacent gate electrodes 120. In some embodiments, the mold insulating layer 122 may be arranged between the upper surface of the substrate 110 and the gate electrode 120 at the bottom, and the mold insulating layer 122 may also be on the upper surface of the gate electrode 120 at the top.

In some embodiments, the gate electrodes 120 may each include a metal, such as tungsten, nickel, cobalt, tantalum, etc., metal silicide, such as tungsten silicide, nickel silicide, cobalt silicide, tantalum silicide, etc., doped polysilicon, or a combination thereof. In some embodiments, the mold insulating layers 122 may include silicon oxide.

In some embodiments, the gate electrodes 120 may each correspond to the ground select line GSL, the word lines WL: WL1, WL2, . . . , WLn−1, and WLn, and at least one string select line SSL constituting the memory cell strings MS (see FIG. 2). For example, the gate electrode 120 at the top may function as the ground select line GSL, two gate electrodes 120 at the bottom may function as the string select line SSL, and the remaining gate electrodes 120 may function as the word line WL. Accordingly, the memory cell strings MS may be provided in which the ground select transistor GST, the string select transistor SST, and the memory cell transistors MC1, MC2, . . . , MCn−1, and MCn therebetween are connected in series. In some embodiments, at least one of the gate electrodes 120 may function as a dummy word line, but the disclosure is not limited thereto.

A stack separation insulating layer WLI may be arranged in a gate stack separation opening portion WLH extending in the vertical direction Z by penetrating the gate electrodes 120 and the mold insulating layers 122. The stack separation insulating layer WLI may have an upper surface at a higher vertical level than the gate electrode 120 at the top, and protrude upwards based on the gate electrode 120 at the top. As illustrated in FIG. 3, the gate electrodes 120 arranged between a pair of gate stack separation opening portions WLH may constitute one block BLK. Furthermore, in one block BLK, at least one gate electrode 120 (e.g., the gate electrode 120 at the top) may be separated into two gate electrodes 120 by a string separation opening portion SSLH. A string separation insulating layer SSLI may be arranged in the string separation opening portion SSLH.

Each of the vertical structures VS may extend in the vertical direction Z by penetrating the gate electrodes 120 and the mold insulating layers 122. In some embodiments, each of the vertical structures VS may include a channel layer 130 extending in the vertical direction Z and a plurality of electrochemical cells 140 disposed on an outer wall of the channel layer 130. Each of the vertical structures VS may further include an embedded insulating pillar 132 surrounded by the channel layer 130 and extending in the vertical direction Z, and a drain conductive layer 134 disposed on the channel layer 130 and an upper surface of the embedded insulating pillar 132.

In some embodiments, the channel layer 130 may be arranged within a vertical opening portion VSH that penetrates the gate electrodes 120 and the mold insulating layers 122 and extends in the vertical direction Z. The channel layer 130 may have a cylindrical shape extending in the vertical direction Z within the vertical opening portion VSH, and the bottom surface of the channel layer 130 arranged in a bottom portion of the vertical opening portion VSH may be in contact with the upper surface of the substrate 110.

In some embodiments, the channel layer 130 may include at least one of tungsten oxide, indium gallium zinc oxide, indium zinc oxide, zinc oxide, zinc tin oxide, indium oxide, titanium oxide, praseodymium chromium manganese oxide, polysilicon, or crystalline silicon.

In some embodiments, the channel layer 130 may have a cylindrical shape extending in the vertical direction Z within the vertical opening portion VSH, and the embedded insulating pillar 132 may be disposed on the inner wall of the channel layer 130. In some embodiments, the channel layer 130 may be configured with portions having a conformal thickness surrounding a side wall and a bottom surface of the embedded insulating pillar 132. For example, a bottom portion of the channel layer 130 may be arranged between a bottom surface of the embedded insulating pillar 132 and the upper surface of the substrate 110, and the bottom portion of the channel layer 130 may be referred to as a horizontal extension portion 130_P of the channel layer 130. A portion of the channel layer 130 disposed on a side wall of the embedded insulating pillar 132 may be referred to as a vertical extension portion 130_V of the channel layer 130. The thickness of the vertical extension portion 130_V of the channel layer 130 and the thickness of the horizontal extension portion 130_P of the channel layer 130 may be the same as or similar to each other.

In some embodiments, the embedded insulating pillar 132 may be omitted and the channel layer 130 may be formed in a vertical pillar shape extending in the vertical direction Z.

The electrochemical cells 140 may be spaced apart from each other in the vertical direction Z on an outer wall OS of the vertical extension portion 130_V of the channel layer 130. Each of the electrochemical cells 140 may be arranged between the outer wall OS of the vertical extension portion 130_V of the channel layer 130 and each of the gate electrodes 120. Each of the electrochemical cells 140 may be formed in a circular or ring shape surrounding the outer wall OS of the vertical extension portion 130_V of the channel layer 130.

In some embodiments, an electric field may be formed inside the electrochemical cells 140 by a voltage applied to each of the gate electrodes 120, the substrate 110, and the drain conductive layer 134, and the electrochemical cells 140 may include a material which enables diffusion or migration of oxygen ions or oxygen vacancy by the formation of an electric field.

In some embodiments, the electrochemical cells 140 may be electrochemical cells based on metal oxide. The electrochemical cell based on metal oxide may be driven by using a principle that oxygen ions or oxygen vacancy included in the metal oxide reversibly migrate due to the electric field formed in the metal oxide.

In some embodiments, in a first mode or a programming mode, that is, when a program voltage is applied to each of the gate electrodes 120, the electrochemical cells 140 may have a high resistance state by the migration of oxygen ions or oxygen vacancy inside the electrochemical cells 140 in one direction. In a second mode or an erase mode, that is, when an erase voltage is applied to each of the gate electrodes 120, the electrochemical cells 140 may have a low resistance state by the migration of oxygen ions or oxygen vacancy inside the electrochemical cells 140 in the opposite direction. Reversely, while the electrochemical cells 140 may have a low resistance state in the first mode or the programming mode, and the electrochemical cells 140 may have a high resistance state in the second mode or the erase mode. Data stored in the electrochemical cells 140 may be read according to a difference in the resistance state of the electrochemical cells 140 between the first mode and the second mode.

In some embodiments, each of the electrochemical cells 140 may include a resistive switching layer 142, an electrolyte layer 144, and a reservoir layer 146.

In some embodiments, the resistive switching layer 142, the electrolyte layer 144, and the reservoir layer 146 may be arranged to sequentially surround the outer wall OS of the vertical extension portion 130_V. For example, the resistive switching layer 142 may be in contact with the outer wall OS of the vertical extension portion 130_V on the outer wall OS of the vertical extension portion 130_V of the channel layer 130. In some embodiments, the resistive switching layer 142 may include tungsten oxide.

In some embodiments, the electrolyte layer 144 may be disposed on an outer wall of the resistive switching layer 142 and in contact with the outer wall of the resistive switching layer 142. The resistive switching layer 142 may be provided between an inner wall of the electrolyte layer 144 and the outer wall OS of the vertical extension portion 130_V of the channel layer 130. In some embodiments, the electrolyte layer 144 may include at least one of hafnium oxide, zirconium oxide, yttrium zirconium oxide (or yttria-stabilized zirconia), or tungsten oxide.

In some embodiments, the reservoir layer 146 may be in contact with the outer wall of the electrolyte layer 144, on the outer wall of the electrolyte layer 144. The electrolyte layer 144 may be provided between an inner wall of the reservoir layer 146 and the outer wall of the resistive switching layer 142. An outer wall of the reservoir layer 146 may be in contact with a corresponding one of the gate electrodes 120 and may be surrounded by the corresponding one of the gate electrodes 120. In some embodiments, the reservoir layer 146 may include at least one of tungsten oxide, gadolinium oxide, molybdenum oxide, tantalum oxide, aluminum oxide, titanium oxide, hafnium oxide, or silicon oxide.

In some embodiments, as illustrated in FIG. 8, the resistive switching layer 142, the electrolyte layer 144, and the reservoir layer 146 may have horizontal cross-sections in a circular or ring shape surrounding the outer wall OS of the vertical extension portion 130_V.

In some embodiments, the electrochemical cells 140 may be spaced apart from each other in the vertical direction Z on the outer wall OS of the vertical extension portion 130_V of one channel layer 130, and the mold insulating layers 122 may each be arranged between two adjacent electrochemical cells 140. In some embodiments, a plurality of first parts P1 of the outer wall OS of the vertical extension portion 130_V of one channel layer 130 may be surrounded by the electrochemical cells 140. A plurality of second parts P2 of the outer wall OS of the vertical extension portion 130_V of one channel layer 130 may be surrounded by the mold insulating layers 122 and in contact with the mold insulating layers 122.

In some embodiments, the mold insulating layers 122 may include a main portion 122M arranged at a position that vertically overlaps the gate electrodes 120, and a ring portion 122R integrally connected to the main portion 122M and in contact with the second parts P2 of the outer wall OS of the vertical extension portion 130_V of the channel layer 130. The ring portion 122R of each of the mold insulating layers 122 may have a ring shape or circular shape in a plan view, as illustrated in FIG. 8, and may surround the second parts P2 of the outer wall OS of the vertical extension portion 130_V of the channel layer 130 from a two-dimensional perspective.

In some embodiments, the electrochemical cells 140 on the outer wall OS of the vertical extension portion 130_V of one channel layer 130 may be arranged at positions vertically overlapping each other, and the electrochemical cells 140 on the outer wall OS of the vertical extension portion 130_V of one channel layer 130 may be arranged at positions vertically overlapping portions (e.g., the ring portion 122R of each of the mold insulating layers 122) of the mold insulating layers 122 surrounding the second parts P2 of the outer wall OS.

In some embodiments, the gate electrodes 120 may each have a first height h11 in the vertical direction Z, the electrochemical cells 140 may each have a second height h12 in the vertical direction Z, and the second height h12 may be greater than the first height h11. In this case, as illustrated in FIG. 7, a step 122ST may be formed on each contact interface between the gate electrodes 120 and the electrochemical cells 140 in a boundary portion between the main portion 122M and the ring portion 122R of each of the mold insulating layers 122.

In some embodiments, the bottom surface of each of the electrochemical cells 140 may be at a lower vertical level than the bottom surface of the gate electrode 120 corresponding thereto, and the top surface of each of the electrochemical cells 140 may be at a higher vertical level than the upper surface of the gate electrode 120 corresponding thereto. The bottom surface of each of the electrochemical cells 140 may be in contact with the top surface of the ring portion 122R of each of the mold insulating layers 122 disposed below each of the electrochemical cells 140. Furthermore, the top surface of each of the electrochemical cells 140 may be in contact with the bottom surface of the ring portion 122R of each of the mold insulating layers 122 disposed above each of the electrochemical cells 140.

In some embodiments, a vertical height h21 of the main portion 122M of each of the mold insulating layers 122 arranged between two adjacent gate electrodes 120 may be greater than a vertical height h22 of the ring portion 122R of each of the mold insulating layers 122 arranged between two adjacent electrochemical cells 140.

An extended portion 120E and the gate pad portion 120P, both connected to the gate electrodes 120, and the cell plug CP1 electrically connected to the gate pad portion 120P, may be arranged in the connection region CON.

In some embodiments, the gate electrodes 120 may extend to the connection region CON, and portions of the gate electrodes 120 arranged in the connection region CON may be referred to as the extended portions 120E. The extended portions 120E may have horizontal lengths that gradually decrease in a direction upward from the upper surface of the substrate 110 (a direction away from the upper surface of the substrate 110). The extended portions 120E may each have a step shape, and the gate pad portions 120P may be connected to the end portions of the extended portions 120E.

In some embodiments, as illustrated in FIG. 6, the gate pad portions 120P may each have a thickness in the vertical direction Z that is greater than that of each of the extended portions 120E. In this case, the upper surfaces of the gate pad portions 120P may be at a higher vertical level than the upper surfaces of the extended portions 120E corresponding thereto. In other embodiments, the gate pad portions 120P may have the same thickness as the extended portions 120E in the vertical direction Z, and in this case, the upper surfaces of the gate pad portions 120P may be at the same vertical level as the top surfaces of the extended portions 120E corresponding thereto.

A stack cover insulating layer 124 may be arranged in the connection region CON to surround the gate electrodes 120, the extended portions 120E, and the gate pad portions 120P. The stack cover insulating layer 124 may include a silicon oxide film, a silicon nitride film, SiON, SiOCN, SiCN, or a combination thereof.

In some embodiments, the cell plug CP1 may be arranged within a plug hole CP1H that penetrates the stack cover insulating layer 124 and extends in the vertical direction Z. An upper surface of the gate pad portion 120P may be arranged at the bottom portion of the plug hole CP1H, and a bottom surface of the cell plug CP1 may be placed on the upper surface of the gate pad portion 120P.

In other embodiments, unlike the illustration in FIG. 6, the cell plug CP1 may extend in the vertical direction Z by penetrating the gate pad portion 120P and the extended portions 120E disposed below the pad portion 120P. In this case, a side wall insulating layer may be further arranged between the cell plug CP1 and the extended portions 120E, and thus, the cell plug CP1 is electrically connected to the gate pad portion 120P so as to be electrically insulated from the extended portions 120E disposed below the gate pad portion 120P.

In other embodiments, unlike the illustration in FIG. 6, the extended portions 120E may be formed to have the same length in a horizontal direction, instead of being formed in a step shape. In this case, the cell plugs CP1 having different lengths in the vertical direction Z may be arranged by penetrating the extended portions 120E, and the bottom surface of the cell plug CP1 may be placed on the gate pad portion 120P. In this case, the side wall insulating layer may be further arranged between the cell plug CP1 and the extended portions 120E, and thus, the cell plug CP1 is electrically connected to the gate pad portion 120P so as to be electrically insulated from the extended portions 120E disposed above the gate pad portion 120P.

In the cell array region MCR, a bit line plug BLC may be disposed on the upper surfaces of the vertical structures VS, and the bit line BL may be disposed on an upper surface of the bit line plug BLC. In the connection region CON, a wire line ML may be disposed on the cell plug CP1.

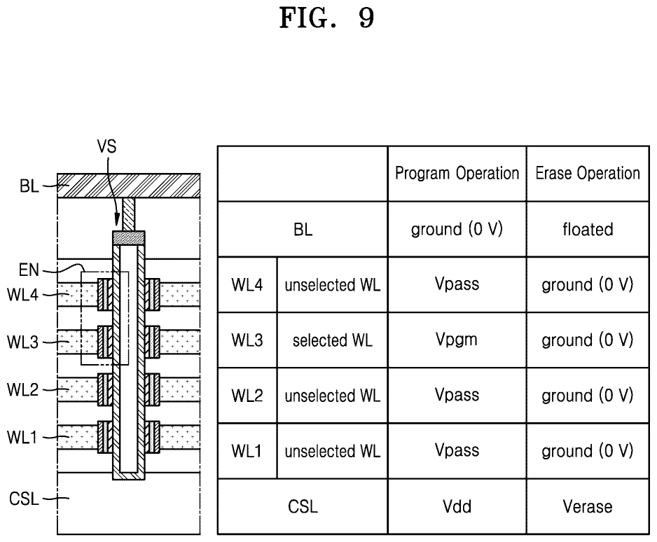

A method of driving the semiconductor device 100 according to some embodiments may be described below in detail with reference to FIGS. 9 to 11.

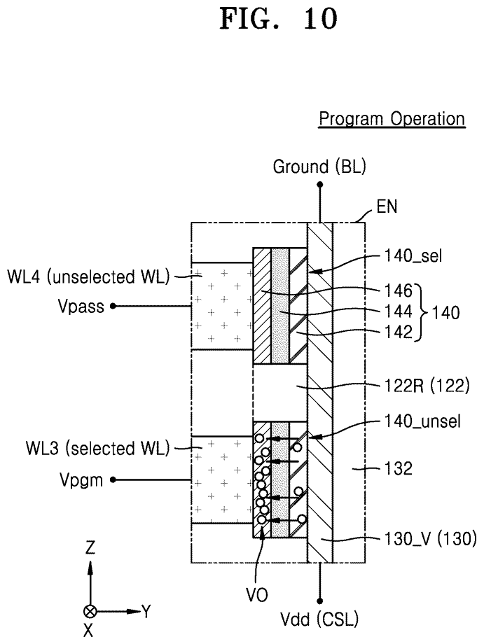

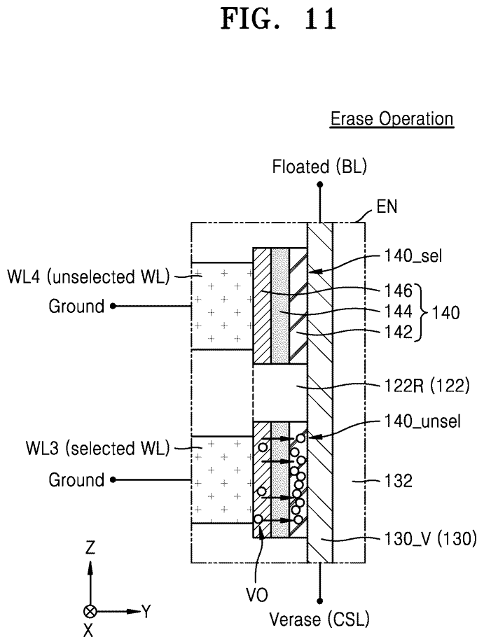

FIG. 9 is a schematic view showing a driving method in a programming mode and an erase mode of a semiconductor device according to some embodiments. FIG. 10 is a schematic diagram showing oxygen vacancy migration in a programming mode within an electrochemical cell. FIG. 11 is a schematic diagram showing oxygen vacancy migration in an erase mode within an electrochemical cell.

Referring to FIGS. 9 to 11, the electrochemical cells 140 of the vertical structure VS may be driven to store data through a programming mode and an erase mode. Data may be stored in the electrochemical cells 140 adjacent to a word line selected in a programming mode, and the data may be erased or deleted from all the electrochemical cells 140 included in the vertical structure VS in an erase mode.

As illustrated in FIG. 9, a case in which, when the first to fourth word lines WL1, WL2, WL3, and WL4 are electrically connected to the vertical structure VS, the third word line WL3 in a programming mode is a select word line is described as an example. In order to store data in the electrochemical cell 140 adjacent to the third word line WL3, a ground voltage of 0 V may be applied to the bit line BL connected to the vertical structure VS, a power voltage Vdd may be applied to the common source line CSL provided in the substrate 110, a program voltage Vpgm may be applied to a selected word line (i.e., the third word line WL3), and a pass voltage Vpass may be applied to an unselected word line (i.e., the first, second, and fourth word lines WL1, WL2, and WL4).

As illustrated in FIG. 10, in a programming mode, when the program voltage Vpgm is applied to the third word line WL3, an electric field may be formed and oxygen vacancies VO may migrate within a selected electrochemical cell 140_sel surrounded by the third word line WL3. For example, due to the electric field formed in the selected electrochemical cell 140_sel between the third word line WL3 and the channel layer 130, the oxygen vacancies VO may migrate from the resistive switching layer 142 to the reservoir layer 146 by passing through the electrolyte layer 144, and thus, the oxygen vacancies VO may be accumulated in the reservoir layer 146. Accordingly, a state in which the oxygen vacancies VO accumulate in the reservoir layer 146 of the selected electrochemical cell 140_sel may be referred to as a state where data is stored (or a state of data ‘0’).

As illustrated in FIG. 10, in the programming mode, an electric field may not be formed inside an unselected electrochemical cell 140_unsel adjacent to an unselected word line, and thus, migration of the oxygen vacancies VO may not occur. Accordingly, the oxygen vacancies VO may not accumulate in the reservoir layer 146 of the unselected electrochemical cell 140_unsel. Furthermore, such a state may be referred to as a state where data is not stored (or a state of data ‘1’).

According to some embodiments, the selected electrochemical cell 140_sel is physically apart from the unselected electrochemical cell 140_unsel. For example, the ring portion 122R of each of the mold insulating layers 122 may be arranged between the selected electrochemical cell 140_sel and the unselected electrochemical cell 140_unsel, and a direct electrical path (or a leakage path) may not be provided between the selected electrochemical cell 140_sel and the unselected electrochemical cell 140_unsel. Accordingly, the oxygen vacancies VO stored in the selected electrochemical cell 140_sel may be prevented or blocked from diffusing or migrating toward the unselected electrochemical cell 140_unsel adjacent thereto. Accordingly, crosstalk or loss of the data stored in the electrochemical cells 140 may be prevented, and a semiconductor device having the structure described above may have excellent reliability or excellent durability.

As illustrated in FIG. 9, in order to delete or reset the data stored in the electrochemical cell 140 adjacent to the third word line WL3, in an erase mode, the bit line BL connected to the vertical structure VS floats, an erase voltage Verase may be applied to the common source line CSL provided in the substrate 110, and the ground voltage of 0 V may be applied to all word lines (i.e., the first to fourth word lines WL1, WL2, WL3, and WL4).

As illustrated in FIG. 11, in an erase mode, when the ground voltage is applied to the third word line WL3 and the erase voltage Verase is applied to the common source line CSL, an electric field is formed in the selected electrochemical cell 140_sel surrounded by the third word line WL3 and the oxygen vacancies VO may migrate. For example, due to the electric field formed in the selected electrochemical cell 140_sel between the third word line WL3 and the channel layer 130, the oxygen vacancies VO may migrate from the reservoir layer 146 into the resistive switching layer 142 by passing through the electrolyte layer 144, the oxygen vacancies VO accumulated in the reservoir layer 146 may be all removed. Accordingly, all the electrochemical cells 140 connected to the vertical structure VS may be in a state where data is not stored (or a state of data ‘1’).

In the semiconductor device 100 according to some embodiments described with reference to FIGS. 3 to 8, the electrochemical cells 140 may be spaced apart from each other in the vertical direction Z on a side wall of one channel layer 130. Accordingly, when one of the electrochemical cells 140 is programmed, diffusion or migration of the oxygen vacancies VO into the electrochemical cell 140 adjacent thereto (i.e., the unselected electrochemical cell 140_unsel) may be prevented. Accordingly, the semiconductor device 100 may have excellent reliability or excellent durability.

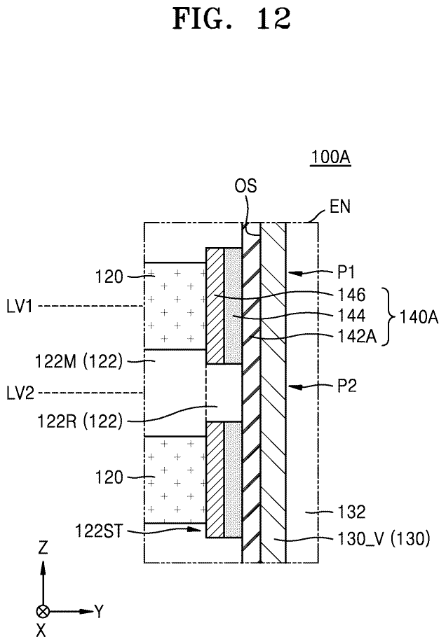

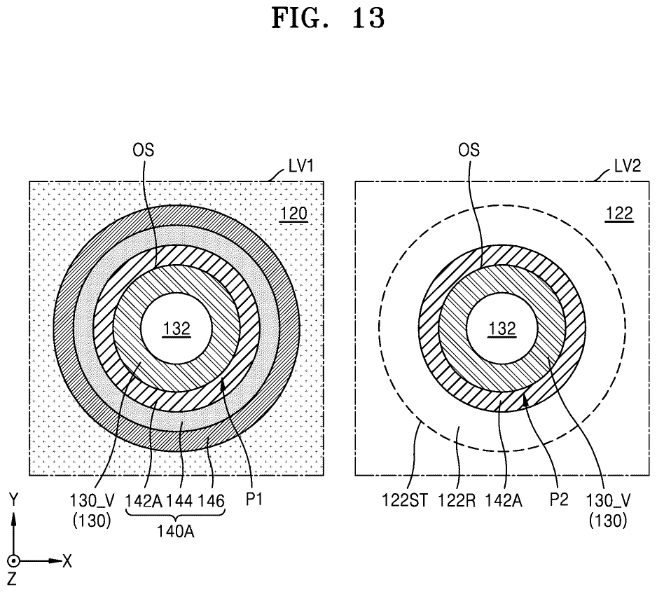

FIG. 12 is a cross-sectional view of a semiconductor device 100A according to some embodiments. FIG. 13 shows plan views of the semiconductor device 100A at the first vertical level LV1 and the second vertical level LV2 in FIG. 12.

Referring to FIGS. 12 and 13, a resistive switching layer 142A included in each of a plurality of electrochemical cells 140A may continuously extend along the outer wall OS of the channel layer 130. Accordingly, the resistive switching layer 142A may have a cylindrical shape continuously extending over the total length of one channel layer 130 along the outer wall OS of one channel layer 130, and the resistive switching layer 142A may be shared by the electrochemical cells 140A.

As illustrated in FIG. 13, at the second vertical level LV2, the outer wall OS of the channel layer 130 may be not in contact with the ring portion 122R of each of the mold insulating layers 122, but the outer wall of the resistive switching layer 142A may be in contact with the ring portion 122R of each of the mold insulating layers 122.

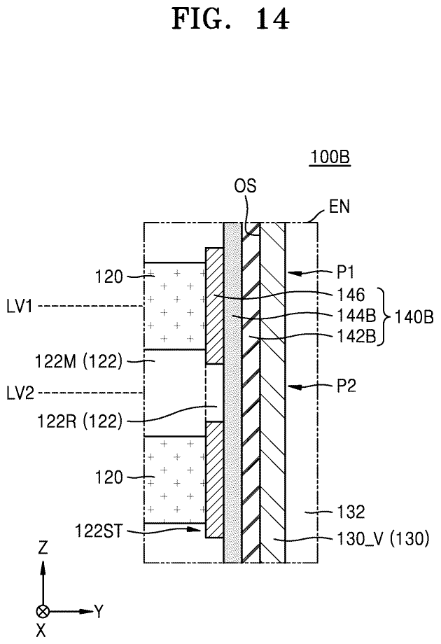

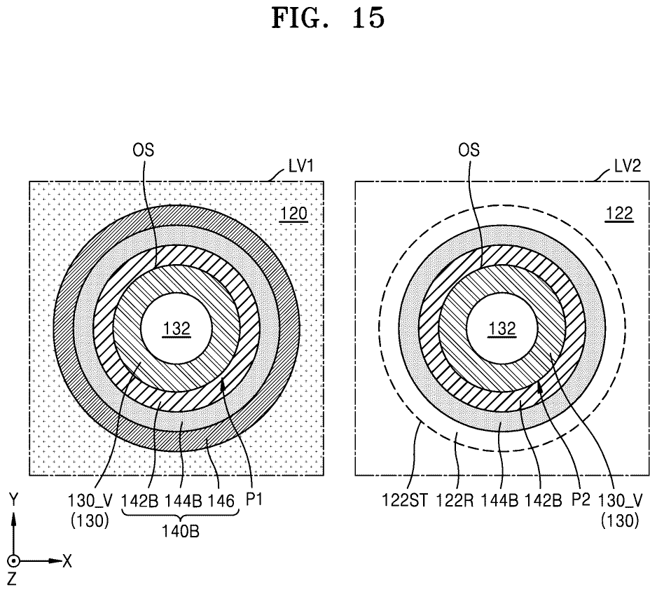

FIG. 14 is a cross-sectional view of a semiconductor device 100B according to some embodiments. FIG. 15 shows plan views of the semiconductor device 100B at the first vertical level LV1 and the second vertical level LV2 in FIG. 14.

Referring to FIGS. 14 and 15, a resistive switching layer 142B and an electrolyte layer 144B included in each of a plurality of electrochemical cells 140B may continuously extend along the outer wall OS of the channel layer 130. Accordingly, the resistive switching layer 142B and the electrolyte layer 144B may have a cylindrical shape continuously extending over the total length of one channel layer 130 along the outer wall OS of one channel layer 130, and the resistive switching layer 142B and the electrolyte layer 144B may be shared by the electrochemical cells 140B.

As illustrated in FIG. 15, at the second vertical level LV2, the outer wall OS of the channel layer 130 may not be in direct contact with the ring portion 122R of each of the mold insulating layers 122, but the outer wall of the resistive switching layer 142B is surrounded by the electrolyte layer 144B. Accordingly, the outer wall of the electrolyte layer 144B may be surrounded by the ring portion 122R of each of the mold insulating layers 122 and in contact with the ring portion 122R of each of the mold insulating layers 122.

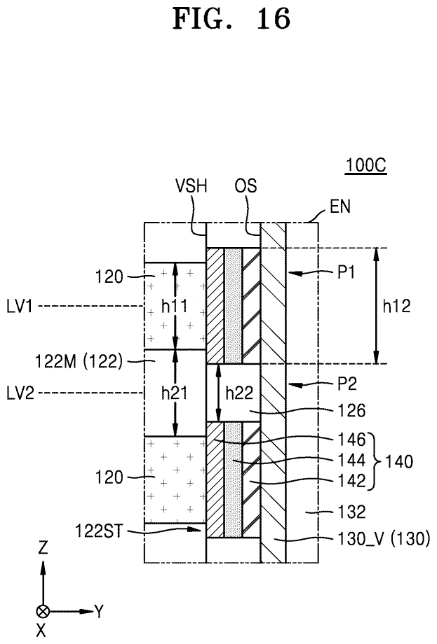

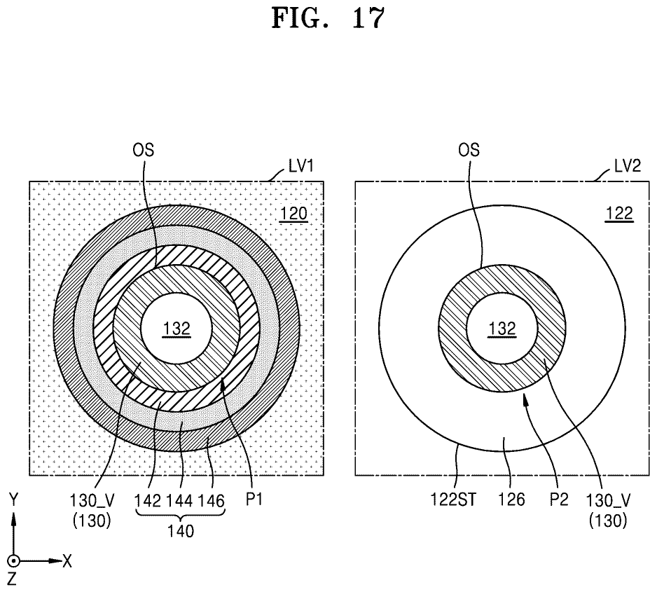

FIG. 16 is a cross-sectional view of a semiconductor device 100C according to some embodiments. FIG. 17 shows plan views of the semiconductor device 100C at the first vertical level LV1 and the second vertical level LV2 in FIG. 16.

Referring to FIGS. 16 and 17, instead of forming the ring portion 122R of each of the mold insulating layers 122, a liner layer 126 may be arranged between two adjacent electrochemical cells 140 in the vertical direction Z. The liner layer 126 may surround the outer wall OS of the vertical extension portion 130_V of the channel layer 130.

In some embodiments, the liner layer 126 may include at least one of silicon oxide, silicon nitride, silicon oxynitride, or a low-k dielectric material. In some embodiments, the liner layer 126 may be formed by a method of filling space between the electrochemical cells 140 after the electrochemical cells 140 are formed on the inner wall of the vertical opening portion VSH. In some other embodiments, a plurality of liner layers 126 may be first formed on the inner wall of the vertical opening portion VSH, and then the electrochemical cells 140 may be formed in the space between the liner layers 126.

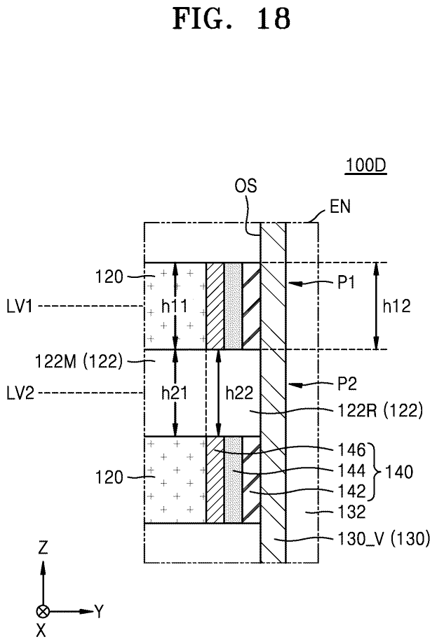

FIG. 18 is a cross-sectional view of a semiconductor device 100D according to some embodiments.

Referring to FIG. 18, the gate electrodes 120 may each have the first height h11 in the vertical direction Z, the electrochemical cells 140 may each have the second height h12 in the vertical direction Z, and the second height h12 may be substantially the same as or similar to the first height h11. A value being substantially the same or similar to another value may mean that one value is within about 5% or about 10% of a deviation from the other value, and that both one value and the other are within a range variable from a target value considering mistakes, misalignments, tolerances, or the like in a manufacturing process.

As the second height h12 in the vertical direction Z of each of the electrochemical cells 140 is substantially the same as or similar to the first height h11 in the vertical direction Z of each of the gate electrodes 120, the height h21 in the vertical direction Z of the main portion 122M of each of the mold insulating layers 122 may be substantially the same as or similar to the height h22 in the vertical direction Z of the ring portion 122R of each of the mold insulating layers 122. Accordingly, on the contact interface between the gate electrodes 120 and the electrochemical cells 140, no step may be formed in a boundary portion between the main portion 122M and the ring portion 122R of each of the mold insulating layers 122.

In some embodiments, the bottom surface of each of the electrochemical cells 140 may be at the same vertical level as the bottom surface of the gate electrode 120 corresponding thereto, and the top surface of each of the electrochemical cells 140 may be at the same vertical level as the top surface of the gate electrode 120 corresponding thereto. Furthermore, the upper surface of the main portion 122M of each of the mold insulating layers 122 may be at the same vertical level as the top surface of the ring portion 122R, and the bottom surface of the main portion 122M of each of the mold insulating layers 122 may be at the same vertical level as the bottom surface of the ring portion 122R.

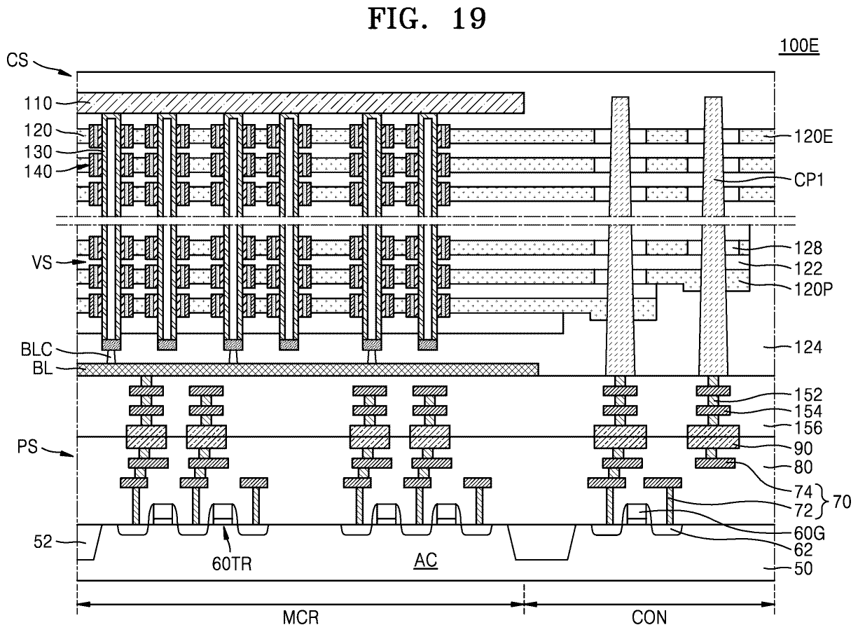

FIG. 19 is a cross-sectional view of a semiconductor device 100E according to some embodiments.

Referring to FIG. 19, the semiconductor device 100E may include a cell array structure CS and a peripheral circuit structure PS overlapping each other in the vertical direction Z. The cell array structure CS may include the memory cell array 20 described with reference to FIG. 1, and the peripheral circuit structure PS may include the peripheral circuit 30 described with reference to FIG. 1.

The peripheral circuit structure PS may include a peripheral circuit transistor 60TR and a peripheral circuit wire structure 70, which are arranged on a substrate 50. An active region AC may be defined by a device separating layer 52 on the substrate 50, and the peripheral circuit transistors 60TR may be formed in the active region AC. The peripheral circuit transistors 60TR may include a peripheral circuit gate 60G and a source/drain region 62 arranged in some parts of the substrate 50 on both sides of the peripheral circuit gate 60G.

The substrate 50 may include a semiconductor material, for example, Group IV semiconductors, Group III-V compound semiconductors, or Group II-VI oxide semiconductors. For example, a Group IV semiconductor may include silicon (Si), germanium (Ge), or silicon-germanium. The substrate 50 may be provided as a bulk wafer or an epitaxial layer. In another embodiment, the substrate 50 may include a silicon-on-insulator (SOI) substrate or a germanium-on-insulator (GeOI) substrate.

The peripheral circuit wire structure 70 may include a plurality of peripheral circuit contacts 72 and the peripheral circuit wire layers 74. An interlayer insulating film 80 for covering the peripheral circuit transistor 60TR and the peripheral circuit wire structure 70 may be arranged on the substrate 50. The peripheral circuit wire layers 74 may have a multilayer structure including a plurality of metal layers located at different vertical levels. A connection pad 90 may be disposed on the interlayer insulating film 80, and the peripheral circuit structure PS and the cell array structure CS may be electrically connected and bonded to each other by the connection pad 90.

A common source layer 110, the gate electrodes 120, and the vertical structures VS extending in the vertical direction Z by penetrating the gate electrodes 120 and connected to the common source layer 110 may be arranged in the cell array structure CS. The vertical structures VS may include the channel layer 130 and the electrochemical cells 140. The extended portion 120E and the pad portion 120P, which are connected to the gate electrodes 120, and the cell plug CP1 electrically connected to the pad portion 120P by penetrating the extended portion 120E and the pad portion 120P, may be arranged in the connection region CON. Insulating patterns 128 may be formed at a position where the insulation patterns 129 vertically overlapping the pad portion 120P that is connected to the cell plug CP1, and the insulating patterns 128 may be provided between the cell plug CP1 and the extended portions 120E.

A connection via 152, a connection wire layer 154, and an interlayer insulating film 156 surrounding the connection via 152 and the connection wire layer 154 may be arranged between the stack cover insulating layer 124 and the peripheral circuit structure PS. The connection via 152 and the connection wire layer 154 may be configured as a multilayer to be located at a plurality of vertical levels, by which the bit line BL and the cell plug CP1 may be electrically connected to the peripheral circuit structure PS through the connection pad 90.

Although FIG. 19 illustrates, as an example, the semiconductor device 100E of a metal-oxide bonding type, in which the cell array structure CS and the peripheral circuit structure PS are attached to each other through the connection pad 90, the disclosure is not limited thereto. A semiconductor device in which the cell array structure CS is arranged directly above the peripheral circuit structure PS without using the connection pad 90, or a bonding type semiconductor device in which the cell array structure CS and the peripheral circuit structure PS are attached to each other without using the connection pad 90, may be implemented.

In the embodiments described with reference to FIGS. 1 to 19, the reservoir layer 146 in one of the electrochemical cells 140 is physically apart from the reservoir layer 146 in an adjacent one of the electrochemical cells 140. Accordingly, the oxygen vacancies stored in the reservoir layer 146 of the selected one of the electrochemical cells 140 may be prevented or blocked from diffusing or migrating toward an adjacent unselected one of the electrochemical cells 140.

In some other embodiments, the reservoir layer 146 in one of the electrochemical cells 140 may extend in the vertical direction Z over the total length of each of the vertical structures VS so as to be connected to the reservoir layer 146 in an adjacent one of the electrochemical cells 140, and the electrolyte layer 144 in one of the electrochemical cells 140 may be physically apart from the electrolyte layer 144 in an adjacent one of the electrochemical cells 140. In other words, each of the vertical structures VS may include the reservoir layer 146 having a cylindrical shape extending in the vertical direction Z, and a plurality of electrolyte layers 144 spaced apart from each other in the vertical direction Z. In this case, the oxygen vacancies stored in the reservoir layer 146 of the selected one of the electrochemical cells 140 may be prevented or blocked from diffusing or migrating toward an adjacent unselected one of the electrochemical cells 140.

In some other embodiments, the reservoir layer 146 in one of the electrochemical cells 140 may extend in the vertical direction Z over the total length of each of the vertical structures VS so as to be connected to the reservoir layer 146 in an adjacent one of the electrochemical cells 140, and the resistive switching layer 142 in one of the electrochemical cells 140 may be physically apart from an adjacent resistive switching layer 142 in one of the electrochemical cells 140. In other words, each of the vertical structures VS may include the reservoir layer 146 having a cylindrical shape extending in the vertical direction Z, and a plurality of resistive switching layers 142 spaced apart from each other in the vertical direction Z. In this case, the oxygen vacancies stored in the reservoir layer 146 of the selected one of the electrochemical cells 140 may be prevented or blocked from diffusing or migrating toward an adjacent unselected one of the electrochemical cells 140.

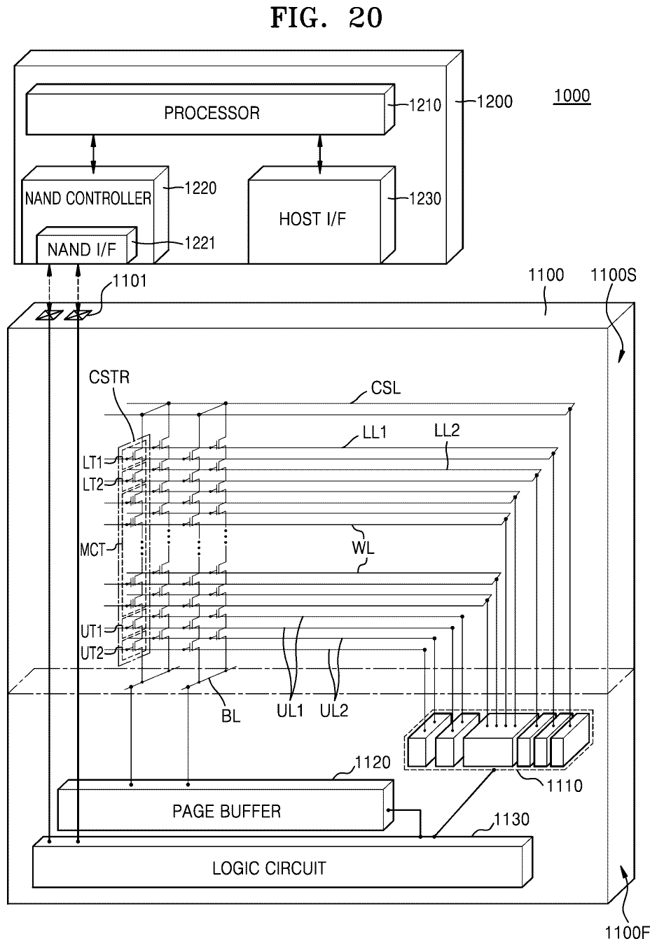

FIG. 20 is a schematic block diagram showing a data storage system 1000 including a semiconductor device according to some embodiments.

Referring to FIG. 20, the data storage system 1000 may include at least one semiconductor device 1100 and a memory controller 1200 electrically connected to the semiconductor device 1100. The data storage system 1000 may include, for example, a solid state drive (SSD) device, a universal serial bus (USB), a computing system, a medical device, or a communication device, each including at least one semiconductor device 1100.

The semiconductor device 1100 may include a non-volatile semiconductor device, and for example, the semiconductor device 1100 may include a NAND flash semiconductor device including one of the semiconductor devices 10, 100, 100A, 100B, 100C, 100D, and 100E described with reference to FIGS. 1 to 19. The semiconductor device 1100 may include a first structure 1100F and a second structure 1100S on the first structure 1100F. The first structure 1100F may include a peripheral circuit structure including a row decoder 1110, a page buffer 1120, and a logic circuit 1130.

The second structure 1100S may include a memory cell structure including the bit lines BL, the common source line CSL, the word lines WL, first and second string select lines UL1 and UL2, first and second ground select lines LL1 and LL2, and a plurality of memory cell strings CSTR between the bit lines BL and the common source line CSL.

In the second structure 1100S, the memory cell strings CSTR may each include ground select transistors LT1 and LT2 adjacent to the common source line CSL, string select transistors UT1 and UT2 adjacent to the bit lines BL, and a plurality of memory cell transistors MCT arranged between the ground select transistors LT1 and LT2 and the string select transistors UT1 and UT2. The number of ground select transistors (e.g. the ground select transistors LT1 and LT2) and the number of string select transistors (e.g., the string select transistors UT1 and UT2) may vary depending on the embodiments.

In some embodiments, the first and second ground select lines LL1 and LL2 may be connected to the gate electrodes of the ground select transistors LT1 and LT2, respectively. The word lines WL may be connected to the gate electrodes of the memory cell transistors MCT. The first and second string select lines UL1 and UL2 may be connected to the gate electrodes of the string select transistors UT1 and UT2, respectively.

The common source line CSL, the first and second ground select lines LL1 and LL2, the word lines WL, and the first and second string select lines UL1 and UL2 may be connected to the row decoder 1110. The bit lines BL may be electrically connected to the page buffer 1120.

The semiconductor device 1100 may communicate with the memory controller 1200 through an I/O pad 1101 electrically connected to the logic circuit 1130. The I/O pad 1101 may be electrically connected to the logic circuit 1130.

The memory controller 1200 may include a processor 1210, a NAND controller 1220, and a host interface (I/F) 1230. In some embodiments, the data storage system 1000 may include a plurality of semiconductor devices 1100, and in this case, the memory controller 1200 may control the semiconductor devices 1100.

The processor 1210 may control the overall operation of the data storage system 1000 including the memory controller 1200. The processor 1210 may operate according to certain firmware, and may access the semiconductor device 1100 by controlling the NAND controller 1220. The NAND controller 1220 may include a NAND I/F 1221 for processing communication with the semiconductor device 1100. Through the NAND I/F 1221, control commands to control the semiconductor device 1100, data to be written to the memory cell transistors MCT of the semiconductor device 1100, data to be read from the memory cell transistors MCT of the semiconductor device 1100 may be transmitted. The host I/F 1230 may provide a communication function between the data storage system 1000 and an external host. When receiving control commands from the external host through the host I/F 1230, the processor 1210 may control the semiconductor device 1100 in response to the received control commands.

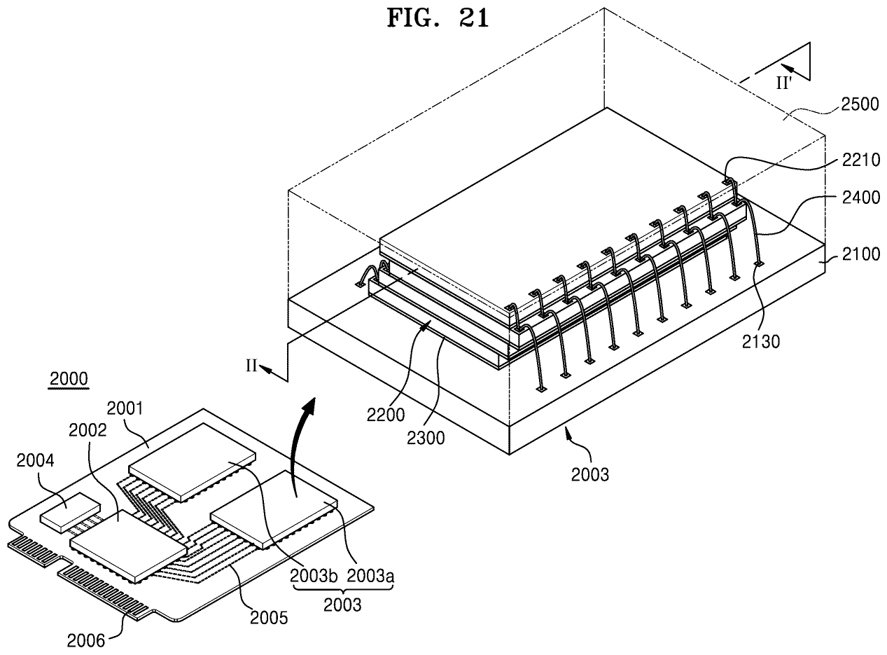

FIG. 21 is a schematic perspective view of a data storage system 2000 including a semiconductor device according to some embodiments.

Referring to FIG. 21, the data storage system 2000 according to an embodiment may include a main substrate 2001, a memory controller 2002 mounted on the main substrate 2001, at least one semiconductor package 2003, and DRAM 2004. The semiconductor package 2003 and the DRAM 2004 may be connected to the memory controller 2002 via a plurality of wire patterns 2005 formed on the main substrate 2001.

The main substrate 2001 may include a connector 2006 including a plurality of pins connected to an external host. The number and arrangement of the pins in the connector 2006 may vary depending on a communication interface between the data storage system 2000 and the external host. In some embodiments, the data storage system 2000 may communicate with the external host according to any one of interfaces, such as USB, peripheral component interconnect express (PCIe), serial advanced technology attachment (SATA), M-Phy for universal flash storage (UFS), etc. In some embodiments, the data storage system 2000 may be operated by power supplied from the external host through the connector 2006. The data storage system 2000 may further include a power management integrated circuit (PMIC) for distributing the power supplied from the external host to the memory controller 2002 and the semiconductor package 2003.

The memory controller 2002 may write data to the semiconductor package 2003 or read data from the semiconductor package 2003, and improve the operating speed of the data storage system 2000.

The DRAM 2004 may be a buffer memory to alleviate a speed difference between the external host and the semiconductor package 2003 that is a data store space. The DRAM 2004 included in the data storage system 2000 may also operate as a kind of cache memory, and may provide a space for temporarily storing data in a control operation on the semiconductor package 2003. When the data storage system 2000 includes the DRAM 2004, the memory controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, a bonding layer 2300 disposed on a lower surface of each of the semiconductor chips 2200, a plurality of connection structures 2400 electrically connecting the semiconductor chips 2200 to the package substrate 2100, and a molding layer 2500 covering the semiconductor chips 2200 and the connection structures 2400 on the package substrate 2100.

The package substrate 2100 may include a printed circuit board including a plurality of package upper pads 2130. The semiconductor chips 2200 may each include I/O pads 2210. The I/O pads 2210 may correspond to the I/O pad 1101 in FIG. 20. The semiconductor chips 2200 may each include at least one of the semiconductor devices 10, 100, 100A, 100B, 100C, 100D, and 100E described with reference to FIGS. 1 to 19.

In some embodiments, the connection structures 2400 may include bonding wires that electrically connect the I/O pads 2210 to the package upper pads 2130. Accordingly, in the first and second semiconductor packages 2003a and 2003b, the semiconductor chips 2200 may be electrically connected to each other by a bonding wire method, and may be electrically connected to the package upper pads 2130 of the package substrate 2100. In some embodiments, in the first and second semiconductor packages 2003a and 2003b, the semiconductor chips 2200 may be electrically connected to each other by a connection structure including through silicon vias (TSV), instead of the connection structures 2400 by the bonding wire method.

In some embodiments, the memory controller 2002 and the semiconductor chips 2200 may be included in one package. In an embodiment, the memory controller 2002 and the semiconductor chips 2200 may be mounted on a separate interposer substrate that is different from the main substrate 2001, and the memory controller 2002 and the semiconductor chips 2200 may be connected to each other by wires formed on the interposer substrate.

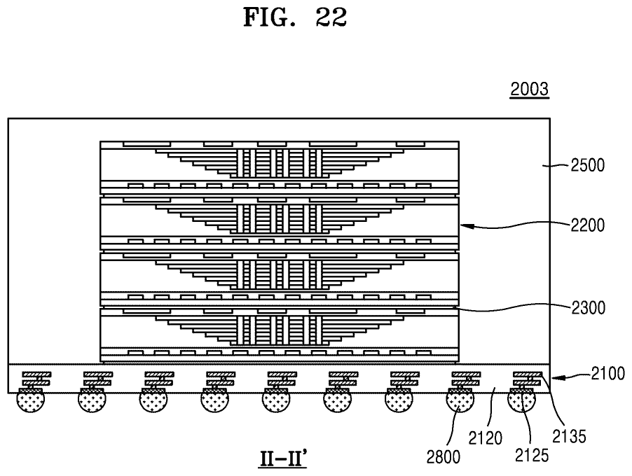

FIG. 22 is a schematic cross-sectional view of the semiconductor package 2003 according to some embodiments. FIG. 22 is a cross-sectional view of the semiconductor package 2003 taken along line II-II′ of FIG. 21.

Referring to FIG. 22, in the semiconductor package 2003, the package substrate 2100 may include a printed circuit board. The package substrate 2100 may include a package substrate body portion 2120, a plurality of package upper pads 2130 (see FIG. 21) disposed on an upper surface of the package substrate body portion 2120, a plurality of lower pads 2125 disposed on a lower surface of the package substrate body portion 2120 or exposed through the lower surface of the package substrate body portion 2120, and a plurality of internal wires 2135 electrically connecting the package upper pads 2130 to the lower pads 2125 inside the package substrate body portion 2120. As illustrated in FIG. 22, the package upper pads 2130 may be electrically connected to the connection structures 2400. As illustrated in FIG. 22, the lower pads 2125 may be electrically connected to the wire patterns 2005 on the main substrate 2001 of the data storage system 2000 in FIG. 22, through a plurality of conductive bumps 2800. The semiconductor chips 2200 may each include at least one of the semiconductor devices 10, 100, 100A, 100B, 100C, 100D, and 100E described with reference to FIGS. 1 to 19.

According to some embodiments, a plurality of electrochemical cells may be disposed on a side wall of one channel layer and include some components spaced apart from each other in a vertical direction, and thus, when one electrochemical cell is programmed, oxygen vacancies may be prevented from diffusing or migrating into adjacent electrochemical cells. Accordingly, the semiconductor device may have excellent reliability or excellent durability.

While the disclosure has been particularly shown and described with reference to preferred embodiments using specific terminologies, the embodiments and terminologies should be considered in descriptive sense only and not for purposes of limitation.

While the inventive concept has been particularly shown and described with reference to embodiments thereof, it will be understood that various changes in form and details may be made therein without departing from the spirit and scope of the following claims.

What is claimed is:

1. A semiconductor device comprising:
a plurality of gate electrodes arranged spaced apart from each other in a vertical direction on a substrate;
a plurality of mold insulating layers alternately arranged with the plurality of gate electrodes on the substrate;
a channel layer extending in the vertical direction by penetrating the plurality of gate electrodes and the plurality of mold insulating layers; and
a plurality of electrochemical cells disposed in the vertical direction on a side wall of the channel layer, each of the plurality of electrochemical cells including a resistive switching layer, an electrolyte layer, and a reservoir layer, which are sequentially arranged on the side wall of the channel layer,
wherein the resistive switching layers of two electrochemical cells immediately adjacent to each other among the plurality of electrochemical cells are spaced apart from each other, the electrolyte layers of the two electrochemical cells immediately adjacent to each other among the plurality of electrochemical cells are spaced apart from each other, and/or the reservoir layers of the two electrochemical cells immediately adjacent to each other among the plurality of electrochemical cells are spaced apart from each other.

2. The semiconductor device of claim 1, wherein the channel layer includes a plurality of first parts and a plurality of second parts,
the plurality of first parts of the channel layer are surrounded by the plurality of electrochemical cells, and
the plurality of second parts of the channel layer are surrounded by the plurality of mold insulating layers.

3. The semiconductor device of claim 2, wherein the plurality of second parts of the channel layer are in contact with the plurality of mold insulating layers.

4. The semiconductor device of claim 1, wherein the plurality of electrochemical cells vertically overlap each other.

5. The semiconductor device of claim 1, wherein each of the plurality of mold insulating layers includes a ring portion, and
the ring portion is arranged at a position that vertically overlaps the plurality of electrochemical cells.

6. The semiconductor device of claim 5, wherein side walls of the plurality of electrochemical cells are surrounded by corresponding gate electrodes, and
bottom surfaces of the plurality of electrochemical cells are in contact with top surfaces of the ring portions of the plurality of mold insulating layers.

7. The semiconductor device of claim 1, wherein each of the plurality of gate electrodes has a first height in the vertical direction, and
each of the plurality of electrochemical cells has a second height that is greater than the first height in the vertical direction.

8. The semiconductor device of claim 1, wherein the channel layer includes at least one of tungsten oxide, indium gallium zinc oxide, indium zinc oxide, zinc oxide, zinc tin oxide, indium oxide, titanium oxide, praseodymium chromium manganese oxide, polysilicon, or crystalline silicon, and
the reservoir layer includes at least one of tungsten oxide, gadolinium oxide, molybdenum oxide, tantalum oxide, aluminum oxide, titanium oxide, hafnium oxide, or silicon oxide.

9. The semiconductor device of claim 1, wherein the resistive switching layer includes tungsten oxide, and
the electrolyte layer includes at least one of hafnium oxide, zirconium oxide, yttrium zirconium oxide, or tungsten oxide.

10. The semiconductor device of claim 1, wherein each of the resistive switching layer, the electrolyte layer, and the reservoir layer has a circular or ring shape from a two-dimensional perspective.

11. A semiconductor device comprising:
a plurality of gate electrodes and a plurality of mold insulating layers, which are alternately arranged on a substrate;
a channel layer extending in a vertical direction by penetrating the plurality of gate electrodes and the plurality of mold insulating layers; and
a plurality of electrochemical cells disposed in the vertical direction on a side wall of the channel layer, each of the plurality of electrochemical cells including a resistive switching layer, an electrolyte layer, and a reservoir layer, which are sequentially arranged on the side wall of the channel layer,
wherein each of the plurality of mold insulating layers includes a ring portion disposed on the side wall of the channel layer, and the ring portion is arranged between a first electrochemical cell and a second electrochemical cell among the plurality of electrochemical cells, and
the resistive switching layers of the first and second electrochemical cells are spaced apart from each other, the electrolyte layers of the first and second electrochemical cells are spaced apart from each other, and/or the reservoir layers of the first and second electrochemical cells are spaced apart from each other.

12. The semiconductor device of claim 11, wherein the ring portion overlaps the first electrochemical cell and the second electrochemical cell in the vertical direction.

13. The semiconductor device of claim 11, wherein the channel layer includes a plurality of first parts and a plurality of second parts,
the plurality of first parts of the channel layer are surrounded by the plurality of electrochemical cells, and
the plurality of second parts of the channel layer are surrounded by the ring portions of the plurality of mold insulating layers.

14. The semiconductor device of claim 13, wherein the plurality of second parts of the channel layer are in contact with the ring portions of the plurality of mold insulating layers.

15. The semiconductor device of claim 11, wherein side walls of the plurality of electrochemical cells are surrounded by corresponding gate electrodes, and
bottom surfaces of the plurality of electrochemical cells are in contact with top surfaces of the ring portions of the plurality of mold insulating layers.

16. The semiconductor device of claim 11, wherein top surfaces of the plurality of electrochemical cells are at a higher vertical level than top surfaces of corresponding gate electrodes among the plurality of gate electrodes, and
bottom surfaces of the plurality of electrochemical cells are at a lower vertical level than bottom surfaces of corresponding gate electrodes among the plurality of gate electrodes.

17. The semiconductor device of claim 11, wherein a part of the mold insulating layer arranged between two adjacent gate electrodes in the vertical direction has a vertical height greater than a vertical height of the ring portion arranged between two adjacent electrochemical cells among the plurality of electrochemical cells in the vertical direction.

18. A semiconductor device comprising:
a plurality of gate electrodes arranged spaced apart from each other in a vertical direction on a substrate, the plurality of gate electrodes including a first gate electrode and a second gate electrode;
a channel layer extending in the vertical direction by penetrating the plurality of gate electrodes;
a first electrochemical cell arranged between a first part of a side wall of the channel layer and the first gate electrode; and
a second electrochemical cell arranged between a second part of the side wall of the channel layer and the second gate electrode, the second electrochemical cell overlapping the first electrochemical cell in the vertical direction,
wherein each of the first electrochemical cell and the second electrochemical cell includes:
a resistive switching layer in contact with the channel layer;
an electrolyte layer disposed on a side wall of the resistive switching layer; and
a reservoir layer disposed on a side wall of the electrolyte layer, and
the resistive switching layers of the first and second electrochemical cells are spaced apart from each other, the electrolyte layers of the first and second electrochemical cells are spaced apart from each other, and/or the reservoir layers of the first and second electrochemical cells are spaced apart from each other.

19. The semiconductor device of claim 18, wherein a bottom surface of the first electrochemical cell is at a lower vertical level than a bottom surface of the first gate electrode, and
a top surface of the first electrochemical cell is at a higher vertical level than a top surface of the first gate electrode.

20. The semiconductor device of claim 18, further comprising a plurality of mold insulating layers alternately arranged with the plurality of gate electrodes on the substrate,
wherein each of the plurality of mold insulating layers includes a ring portion, and the ring portion is arranged between the first electrochemical cell and the second electrochemical cell and in contact with the side wall of the channel layer.
